(19) United States
(12) Patent Application Publication
(10) Pub. No.: US 2024/0213005 A1
(43) Pub. Date: Jun. 27, 2024

(54) System and Method for Plasma Processing

(71) Applicant: Tokyo Electron Limited, Tokyo (JP)

(72) Inventors: Merritt Funk, Austin, TX (US); Barton Lane, Austin, TX (US); Yohei Yamazawa, Tokyo (JP)

(21) Appl. No.: 18/146,253

(22) Filed: Dec. 23, 2022

(51) Int. Cl. H01J 37/32; H01P 7/06

(52) U.S. Cl. CPC H01J 37/3299; H01J 37/32091; H01J 37/3211; H01J 37/32165; H01P 7/06; H01J 37/32743; H01J 2237/24564; H01J 2237/24585; H01J 2237/334

(57) ABSTRACT

An apparatus for plasma processing includes an RF power source and a set of resonating structures coupled to the RF power source. The resonating structures include a first region and a second region adjacent to the second region. The first region includes a first antenna and a first coupling circuit, the first coupling circuit being outside a coupling of the RF power source to the first region, where the first coupling circuit is configured to adjust a power distribution of the first region. The second region includes a second antenna.

### TECHNICAL FIELD

The present disclosure generally relates to semiconductor processing technology and, in particular embodiments, to a system and method for plasma processing.

### BACKGROUND

Plasma processing is extensively used in the manufacturing and fabrication of high-density microscopic circuits within the semiconductor industry.

In a plasma processing system, an electromagnetic wave radiated into a plasma chamber generates an electromagnetic field within the chamber. The generated electromagnetic field heats electrons in the chamber. The heated electrons ignite a plasma that treats the substrate in a process such as for etching, deposit, oxidation, sputtering, or the like.

A non-uniform electromagnetic field within the plasma processing chamber may result in a non-uniform treatment of the substrate due to different portions of the substrate being treated with varying densities of plasma. However, non-uniformities may also exist in the plasma processing chamber itself. An apparatus and system that allows for the control of the spatial profile of the electromagnetic field is thus desirable.

### SUMMARY

In accordance with an embodiment an apparatus for plasma processing includes an RF power source and a set of resonating structures coupled to the RF power source. The resonating structures include a first region and a second region adjacent to the second region. The first region includes a first antenna and a first coupling circuit, the first coupling circuit being outside a coupling of the RF power source to the first region, where the first coupling circuit is configured to adjust a power distribution of the first region. The second region includes a second antenna.

In accordance with an embodiment, an apparatus for plasma processing includes a resonating structure, the resonating structure having a cylindrical or axisymmetric shape. The resonating structure includes a plurality of azimuthal regions. A first azimuthal region of the plurality of azimuthal regions includes a first antenna and a first impedance control circuit coupled to the first antenna, the first impedance control circuit configured to shift the resonance of one end of the first antenna. A second azimuthal region of the plurality of azimuthal regions includes a second antenna and a second impedance control circuit coupled to the second antenna.

In accordance with an embodiment, a method for plasma processing includes: loading a substrate into a plasma processing system, where the plasma processing system includes a multiregional resonating structure, the multiregional resonating structure including a first region and a second region adjacent to the first region; igniting plasma by providing a first amount of power to the first region and a second amount of power to the second region, the first amount having a greater area density than the second amount; and performing a plasma process on the substrate, the plasma process including producing a plasma with a uniform density.

It is to be understood that both the foregoing general description and the following detailed description are exemplary and explanatory only and are not restrictive of the disclosure, as claimed.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A is a diagram of an embodiment plasma processing system, in accordance with some embodiments;

FIG. 1B is a cross-sectional view of an embodiment resonating structure, in accordance with some embodiments;

FIG. 1C is a schematic of the embodiment resonating structure of FIG. 1B, in accordance with some embodiments;

FIGS. 1D-1G are schematics of various embodiment circuits for resonating structures, in accordance with some embodiments;

FIGS. 2A and 2B are top and perspective views of an embodiment resonating structure, in accordance with some embodiments;

FIGS. 3A and 3B are cross-sectional views of an embodiment resonating structure, in accordance with some embodiments;

FIGS. 3C-3E are schematics of the embodiment resonating structures of FIGS. 3A and 3B, in accordance with some embodiments;

FIG. 4A is a cross-sectional view of an embodiment resonating structure, in accordance with some embodiments;

FIGS. 4B-4C are schematics of the embodiment resonating structure of FIG. 4A, in accordance with some embodiments;

FIG. 4D is a graph of frequency shifts for antennas with inductive loops, in accordance with some embodiments;

FIGS. 5A-5B are diagrams of control schemes for plasma processing systems, in accordance with some embodiments;

FIG. 6 is a graph of plasma ignition at low pressure, in accordance with some embodiments;

FIGS. 7A-7C are plasma power pulse recipes, in accordance with some embodiments;

FIGS. 8A-10B are schematics of multizone plasma systems, in accordance with some embodiments;

FIGS. 11 and 12 are process flow chart diagrams of methods for plasma processing, in accordance with some embodiments.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

According to one or more embodiments of the present disclosure, this application relates to systems and methods for plasma processing with multizone resonating structures. Each region of the multizone resonating structure can include a single antenna or multiple antennas that are dynamically configured to operate together in real time. The regions can be directly selected and controlled with radio frequency (RF) pulse modulation (e.g., modulating duty cycle, frequency, or power), electronic impedance control, or a combination thereof. Power may also be supplied as continuous wave RF with more than one frequency (with sufficient frequency separation) supplied simultaneously to select and control different regions. Plasma density control can be achieved with high-speed control of power delivery to region, such as pulse-to-pulse power control and control of power within pulses. The region control may enable plasma ignition at extreme low pressures and may be achieved with pulsed plasma. Feedback control of plasma density and low pressure plasma ignition may be enabled with embedding sensors (e.g., optical and voltage sensors) by region.

As an alternative to selecting and controlling regions by delivering power to each region separately with discrete pulse amplitudes and durations, multi-tone power delivery with more than one frequency and amplitude combined may be used to select and control regions. The use of multi-tone power may add complexity. For example, power delivery and measurements may require avoiding a tuning of the frequency separation of two regions from being too close, which may result in an overly complex restriction. As such, the following embodiments are described using separation of power by supplying discrete pulses in order to simplify control and measurement. However, one skilled in the art of RF modulation and measure will understand that multi-tone or frequency modulation (for example, as used in FM radio) is a viable method of power transmission and regional uniformity control, and embodiments including multi-tone or frequency modulation for regional uniformity control are included within the scope of this disclosure.

Control of radial and azimuthal regions in real time may be advantageous for plasma processes used in semiconductor manufacturing such as atomic layer etching (ALE). Plasma density uniformity may be altered by adjusting coupling between antennas to account for non-uniform chamber effects or non-uniformities in wafers to be processed. For example, chamber non-uniformities due to pumping ports or wafer non-uniformities can be compensated for during plasma etching or CVD processes by breaking antenna symmetries with variable tuning between antennas. Uniformity control can be used for matching of radial and azimuthal etching critical dimensions or CVD film thickness patterns in multiple process chambers used to produce a given product. For example, different non-uniformities in different chambers can be compensated for so that each chamber in use produces plasma with the same distribution to achieve uniform results in the different chambers. This may be done in coordination with dose adjustment across multiple wafers during lithography to enable ultra-fine uniformity control.

Metrology can measure non-uniformity of incoming wafers and adjust plasma density uniformity on a wafer-to-wafer basis. Moving locations of maximum resonant currents relative to the antennas (e.g., controlling current flow in antenna arms) can be performing by changing the capacitive or inductive coupling to one side of an antenna arm. The capacitive coupling can be changed by using electronic switching between a capacitor and ground or by opening or closing capacitor segments coupled to the antenna arm. Inductive coupling can be used to control power in the antenna arm with mutual coupling coils in each region to control the magnetic field.

While inventive aspects are described primarily in the context of resonating structures in a plasma processing system, the inventive aspects may be similarly applicable to fields outside the semiconductor industry. Plasma can be used to treat and modify surface properties through functional group addition. For example, to treat surfaces for paint deposit, plasma can convert hydrophobic surfaces to hydrophilic surfaces. Further, the inventive aspects are not limited to plasma. For example, RF can be used to thaw out frozen food or dry out textiles, food, wood, or the like. In these various examples and across industries, controlling an oscillating magnetic field as disclosed herein is advantageous.

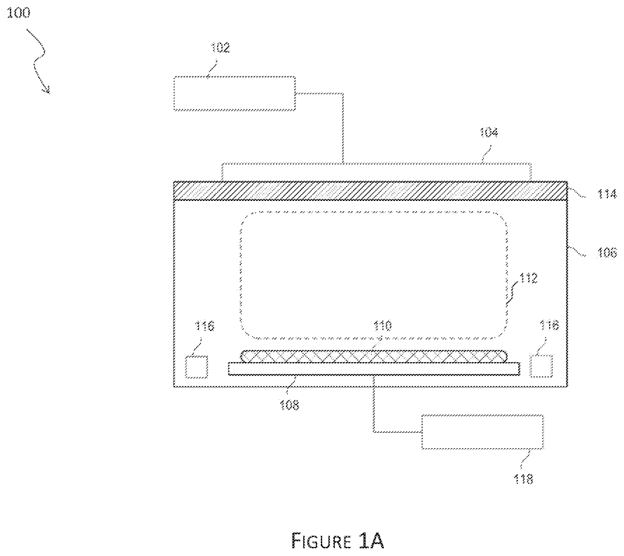

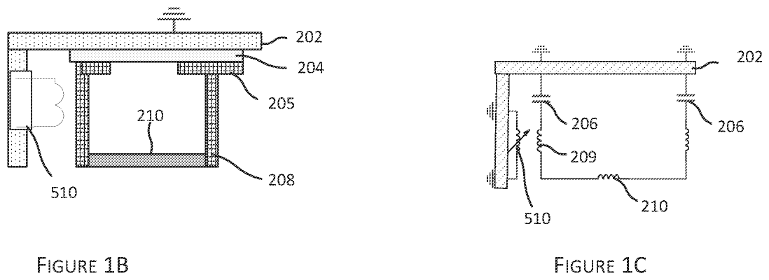

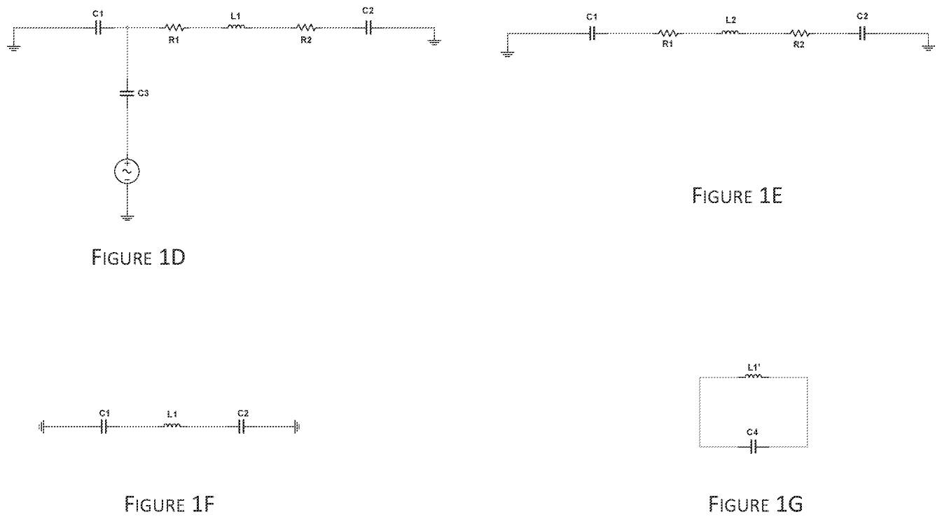

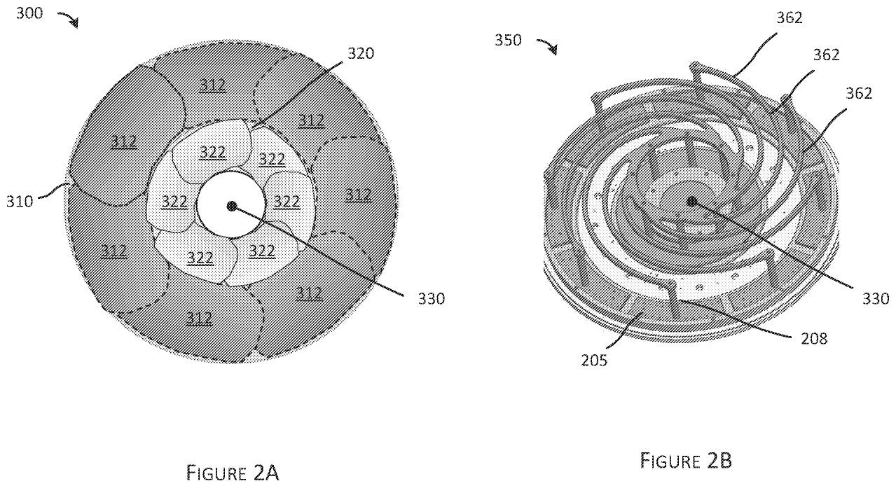

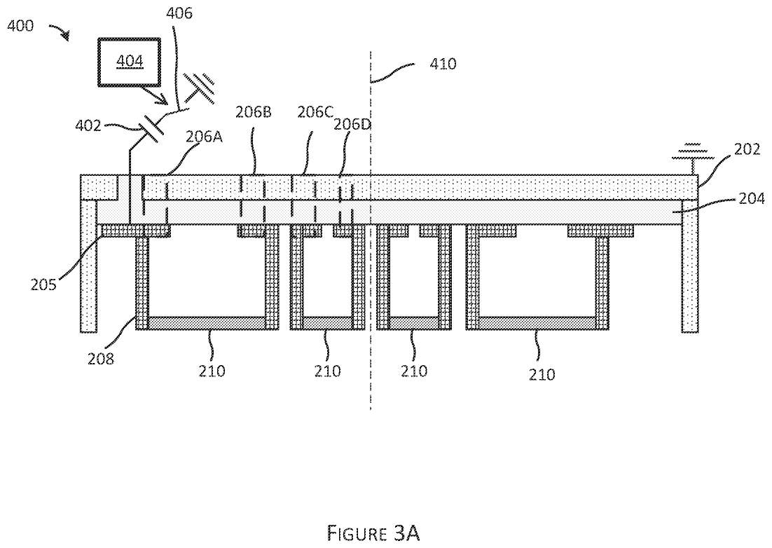

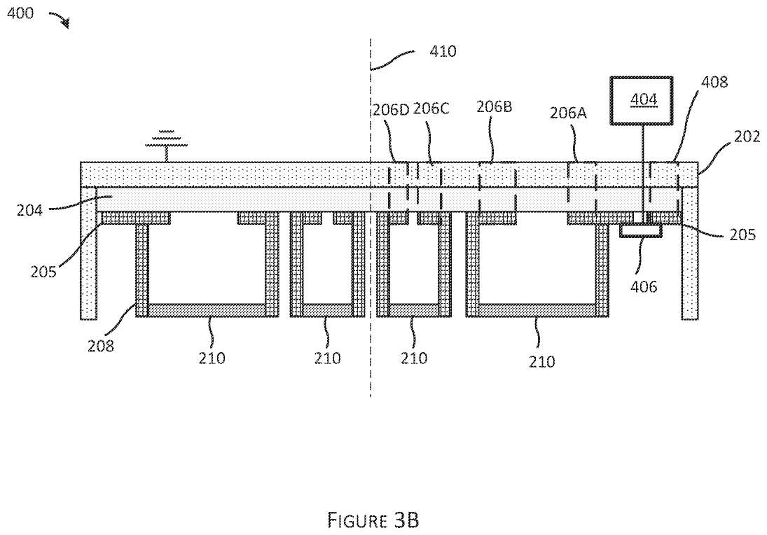

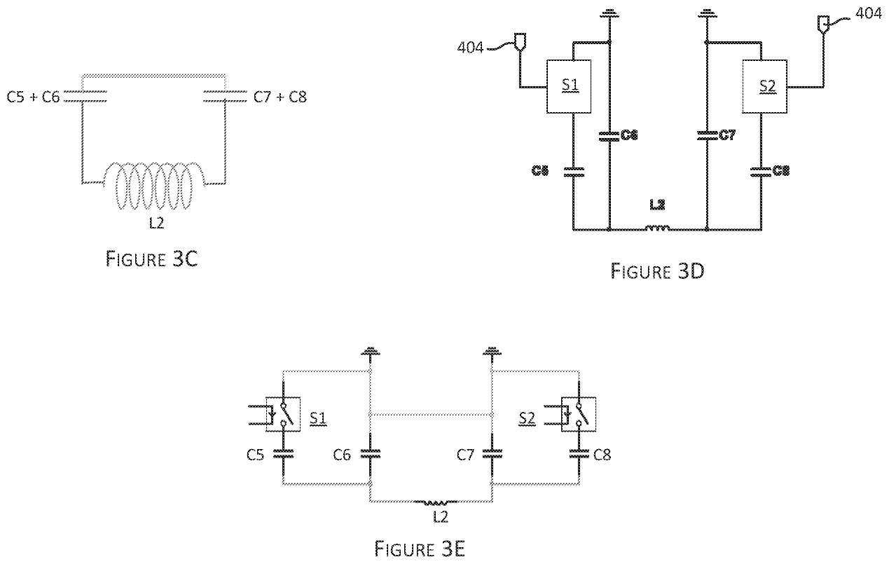

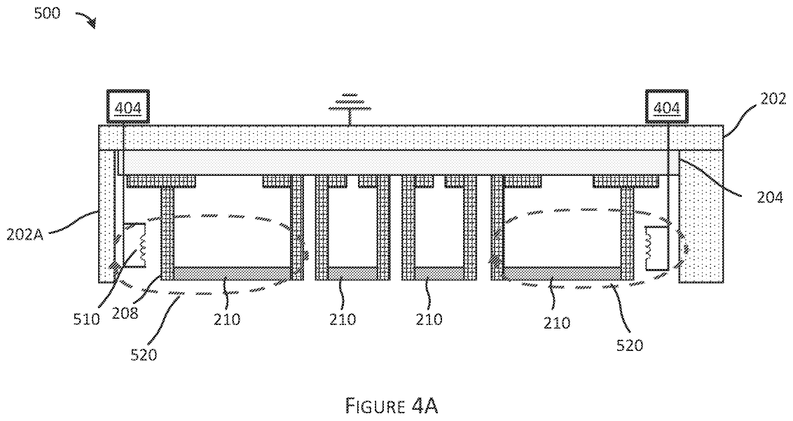

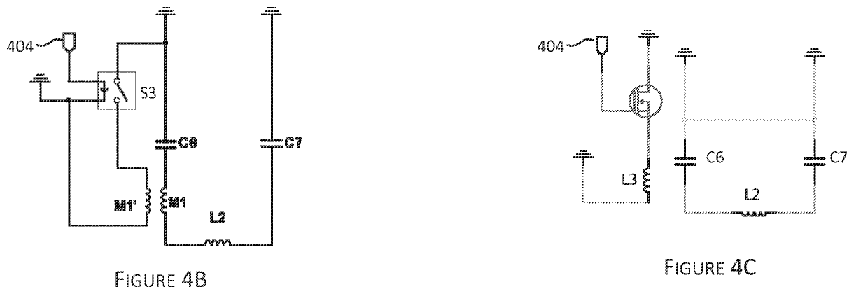

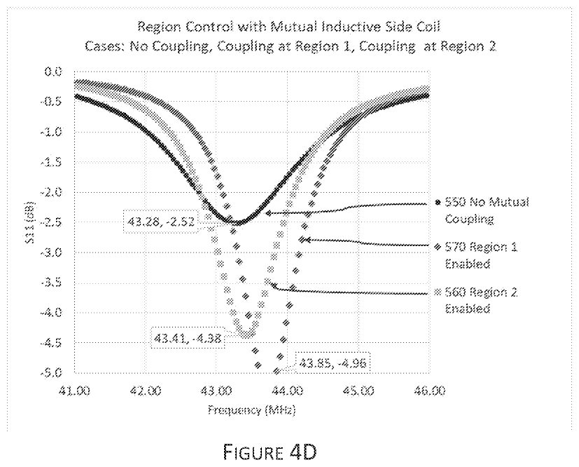

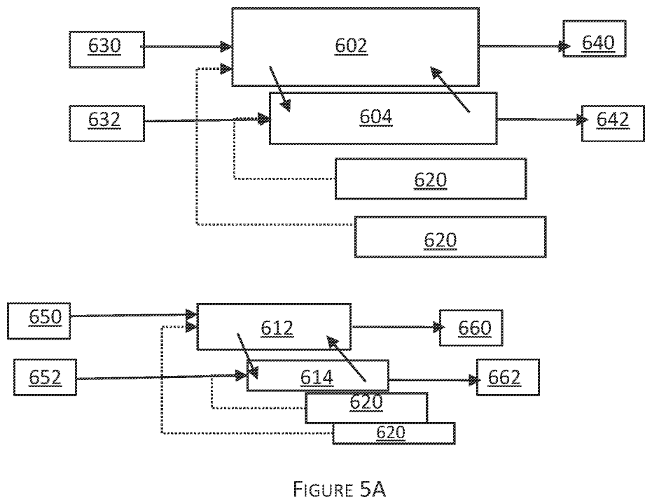

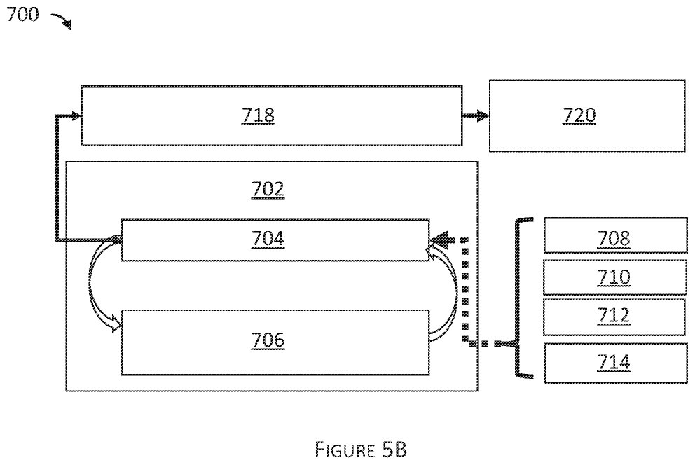

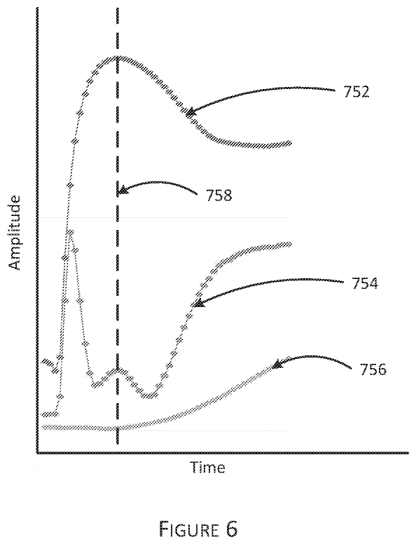

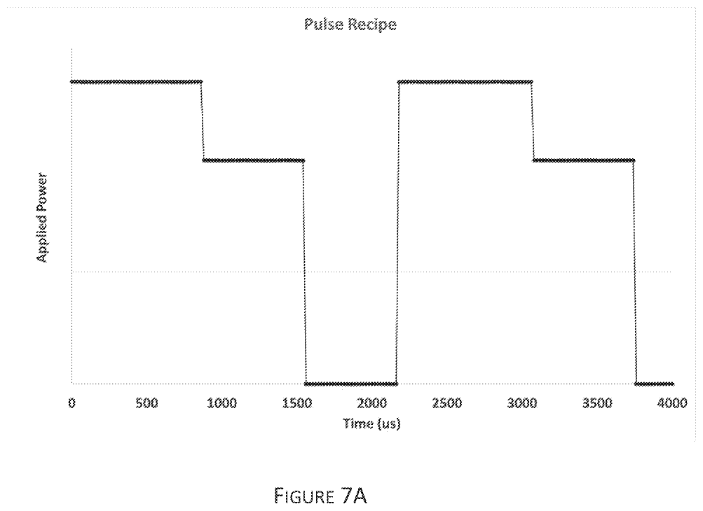

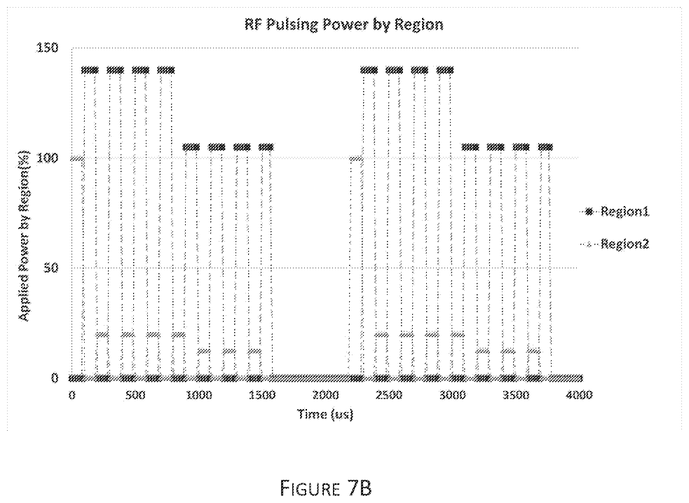

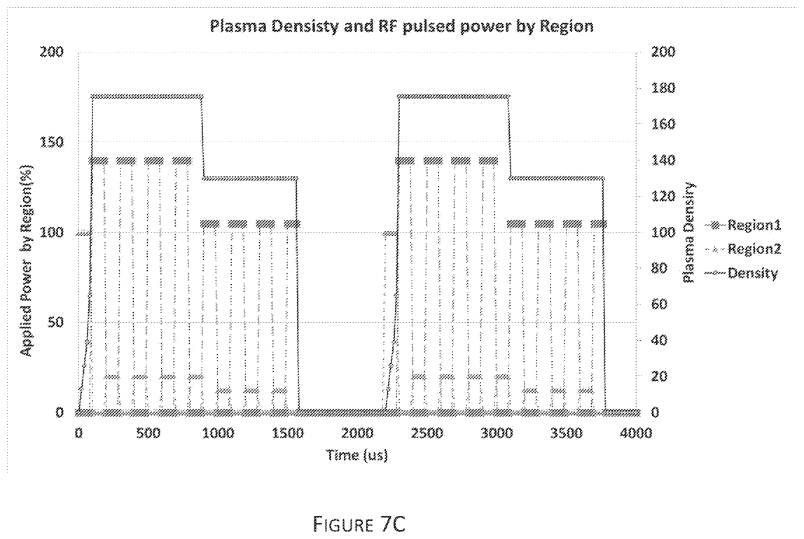

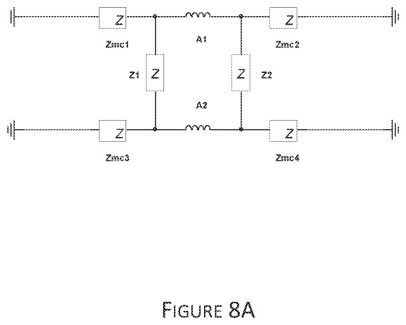

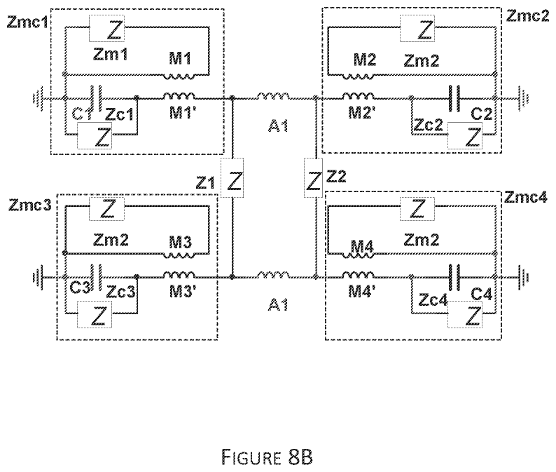

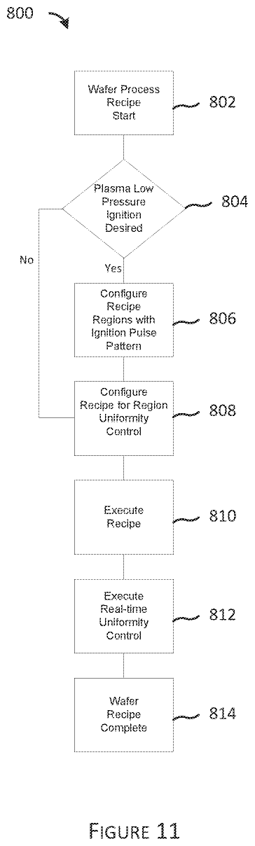

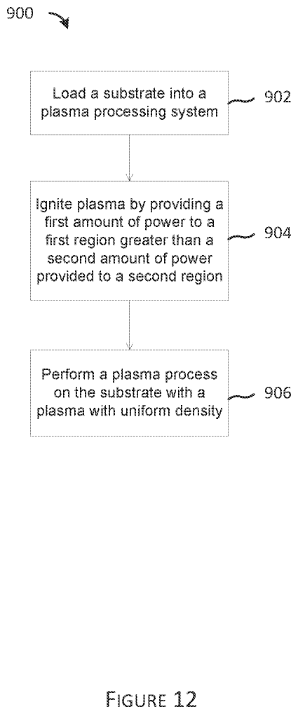

Embodiments of the disclosure are described in the context of the accompanying drawings. An embodiment of a plasma processing system with a resonating structure will be described using FIGS. 1A-1G. An embodiment of a multizone resonating structure will be described using FIGS. 2A-2B. Embodiments of a multizone resonating structure with capacitive circuit tuning will be described using FIGS. 3A-3E. Embodiments of a multizone resonating structure with inductive circuit tuning will be described using FIGS. 4A-4C. Experimental results for frequency shifting with inductive loops will be described using FIG. 4D. Embodiments of control schemes for plasma processing systems will be described using FIGS. 5A-5B. Experimental results for plasma ignition will be described using FIG. 6. Embodiments of plasma power pulse recipes will be described using FIGS. 7A-7C. Embodiments of multizone plasma systems will be described using FIGS. 8A-10B. Embodiments of methods for plasma processing will be described using FIGS. 11 and 12.

FIG. 1A illustrates a diagram of an embodiment plasma processing system 100. The plasma processing system 100 includes an RF source 102 (also referred to as an RF power source), a multizone resonating structure 104, a plasma chamber 106, and, optionally, a dielectric plate 114, which may (or may not) be arranged as shown in FIG. 1A. Further, the plasma processing system 100 may include additional components not depicted in FIG. 1A.

In embodiments, RF source 102 includes an RF power supply, which may include a generator circuit and a matching circuit (not shown). The matching circuit may also be referred to as a matching network. The RF source 102 may supply a single frequency or multiple frequencies. In embodiments, the matching circuit couples the RF source 102 to the multizone resonating structure 104 across one or more capacitors, inductors, or both. In embodiments, the matching circuit is distributed over the multizone resonating structure 104. Impedance of the multizone resonating structure 104 may be different from impedance of the transmission lines between the generator circuit and the multizone resonating structure 104. This difference in impedance can lead to reflected RF power and decreased power efficiency. The matching circuit acts so that the impedance looking into the matching circuit from the generator circuit side is about equal to the internal impedance of the generator circuit. Thus, the matching circuit increases the efficiency of power coupling from the RF source 102 to the multizone resonating structure 104.

In embodiments, the RF source 102 is coupled to the multizone resonating structure 104 via a feeding structure 103. In embodiments, the feeding structure 103 may include a power transmission line, such as a coaxial cable or the like, an interface with conductive offsets (see below, FIG. 1B), the like, or a combination thereof. The RF source 102 provides forward RF waves to the multizone resonating structure 104. The multizone resonating structure 104 (also referred to as a multiregional resonating structure) includes one or more resonating structures (see below, FIG. 2A), also referred to as a set of resonating structures, and one or more radiating structures. In embodiments, the one or more radiating structures are enclosed in a grounded box, which blocks electric fields and reduces magnetic fields for the safety of humans and provides a ground return path from the plasma chamber 106 back to the RF source 102. The forward RF waves travel through the multizone resonating structure 104 and are transmitted (i.e., radiated) towards plasma chamber 106.

Plasma chamber 106 includes a substrate holder 108. As shown, substrate 110 is placed on substrate holder 108 to be processed. Optionally, plasma chamber 106 may include a bias power supply 118 coupled to substrate holder 108. The plasma chamber 106 may also include one or more pump outlets 116 to remove by-products from plasma chamber 106 through selective control of gas flowrates within. In embodiments, pump outlets 116 are placed near (e.g., below/around the perimeter of) substrate holder 108 and substrate 110.

In embodiments, the multizone resonating structure 104 is separated from the plasma chamber 106 by the dielectric plate 114, which is made of a dielectric material. Dielectric plate 114 separates the low-pressure environment within the plasma chamber 106 from the external atmosphere. It should be appreciated that the multizone resonating structure 104 can be placed directly adjacent to the plasma chamber 106, or the multizone resonating structure 104 can be separated from the plasma chamber 106 by air. In embodiments, the dielectric plate 114 is selected to minimize reflections of the RF wave from the plasma chamber 106. In other embodiments, the multizone resonating structure 104 is at least partially embedded within the dielectric plate 114.

In an embodiment, the multizone resonating structure 104 couples RF power from RF source 102 to the plasma chamber 106 to treat the substrate 110. In particular, the multizone resonating structure 104 radiates one or more electromagnetic waves in response to being fed the forward RF waves from the RF source 102. The one or more radiated electromagnetic waves penetrate from the atmospheric side (i.e., the multizone resonating structure 104 side) of the dielectric plate 114 into the plasma chamber 106. The one or more radiated electromagnetic waves generates one or more respective electromagnetic fields within the plasma chamber 106. The generated one or more electromagnetic fields ignite and sustain plasma 112 by transferring energy to free electrons within the plasma chamber 106. The plasma 112 can be used to, for example, selectively etch or deposit material on substrate 110.

In FIG. 1A, the multizone resonating structure 104 is shown to be external to plasma chamber 106. In various embodiments, however, the multizone resonating structure 104 can be placed internal to the plasma chamber 106.

In some embodiments, one or more operating frequencies of the multizone resonating structure 104 are in a range of 1 MHz to 6 GHz. In embodiments, the power delivered by the multizone resonating structure 104 ranges from 10 W to 10 KW, determined by various factors such as distance from the multizone resonating structure 104, impedance values, or the like.

FIG. 1B shows a cross-sectional view of an example resonating structure (also referred to as a cavity), in accordance with some embodiments. The resonating structure may be coupled to ground through one or more capacitive structures (e.g., fixed or variable capacitors). It should be appreciated that the resonating structure of FIG. 1B is a non-limiting example showing possible configurations of a radiating structure, capacitors, and a ground plane without coupling to power, and the example may be coupled to power (e.g., an RF source) to generate plasma.

In FIG. 1B, a radiating structure 210 (also referred to as an antenna) is coupled to a ground plane 202 (also referred to as a conductive plane) through two conductive plates 205. The example resonating structure may have any suitable shape in a top view, such as a round shape, a polygonal shape, or a ring shape (see below, FIG. 2A). In some embodiments, the radiating structure 210 is a spiral antenna. However, the radiating structure 210 may be any structure suitable for generating plasma. In some embodiments, the ground plane 202 is not grounded and is a common plate coupled to ground through, e.g., a matching circuit.

The conductive plates 205 are coupled to the radiating structure 210 by respective conductive offsets 208. Although the conductive offsets 208 are illustrated as being coupled to opposite ends of the radiating structure 210, the conductive offsets 208 may be coupled to any suitable positions on the radiating structure 210. For example, one conductive offset 208 may be coupled to an outer edge of the radiating structure 210, and another conductive offset 208 may be coupled to a center point of the radiating structure 210. The cross-section illustrated in FIG. 2A cuts through the illustrated conductive offsets 208. In embodiments, additional conductive offsets 208 or non-conductive (e.g., insulating) offsets are present between the radiating structure 210 and the conductive plates 205.

The conductive plates 205 are further coupled to the ground plane 202 across an insulating structure 204. The insulating structure 204 consists of an electrically insulating material such as a dielectric material or the like. In embodiments, the insulating structure 204 consists of air or vacuum. In some embodiments, a mutual coupling coil 510 is mounted on a sidewall of the plasma chamber 106 (e.g., a wall extending down from the ground plane 202) to change the resonant frequency of the radiative structure 210 through mutual coupling.

FIG. 1C illustrates a schematic of the example resonating structure of FIG. 1B, also referred to as a floating resonating structure. Each capacitor 206 is formed by a conductive plate 205 coupled to the ground plane 202 across the insulating structure 204. The radiating structure 210 is coupled to the ground plane 202 through the two capacitors 206 so that a capacitor 206 is between the radiating structure 210 and the ground plane 202 on both ends of the radiating structure 210. The two capacitors 206 are representative of the equivalent capacitances of conductive structures including the respective conductive plates 205 and the ground plane 202. In some embodiments in which the radiating structure 210 is an inductor, the radiating structure 210 and the capacitors 206 form a CLC circuit. The mutual coupling coil 510 may have variable inductance for adjusting mutual coupling with an inductor 209 of the conductive offset 208. The conductive offset 208 may include, for example, a one turn equivalent inductor 209 that couples with the mutual coupling coil 510.

FIGS. 1D through 1G are various schematics of circuits for, e.g., the example resonating structure of FIG. 1B, in accordance with some embodiments. FIG. 1D illustrates a schematic for a resonating structure with an antenna L1 (corresponding to the radiating structure 210) that is coupled on one end to ground (e.g., a ground plane 202) across a resistor R1 and a capacitor C1 (corresponding to a capacitor 206) and on the opposite end to ground across a resistor R2 and a capacitor C2 (corresponding to a capacitor 206). By adjusting the capacitances of the capacitors C1 and C2 and the inductance of the antenna L1, the resonant frequency of the antenna L1 may be adjusted. In some embodiments, the antenna L1 has an inductance in a range of 10 nanohenries (nH) to 10,000 nH, such as 1650 nH, the resistor R1 has a resistance in a range of 0.001 (2 to 0.2Ω, such as 0.01Ω, and the capacitor C1 has a capacitance in a range of 10 picofarads (pF) to 10,000 pF, such as 900 pF. A node between the resistor R1 and the capacitor C1 is further coupled to a driving power source across a capacitor C2. In some embodiments, the capacitor C2 has a capacitance in a range of 5 pF to 10,000 pF, such as 200 pF. With the above values for the capacitances of the capacitors C1 and C2 and the inductance of the antenna L1, the frequency of resonance for a single antenna (e.g., the antenna L1) may be in a range of 400 kHz to 2 GHz. In some embodiments, capacitors C1 or C2 can be shorted to ground and the circuit can operate as a LC circuit. FIG. 1E illustrates a schematic for a resonating structure similar to the schematic of FIG. 1D but without a connection to driving power. Power coupling may be through an inductive drive circuit (not illustrated), examples of which are described in U.S. patent application Ser. No. 17/748,737, which is incorporated herein by reference in its entirety.

FIG. 1F illustrates a schematic for a resonating structure similar to the schematic of FIG. 1E that does not include resistors R1 and R2. FIG. 1F is a general schematic of a CLC circuit that enables adjusting the peak current from one end of the antenna L1 near the capacitor C1 to the opposite end at the coupling of the antenna L1 with the capacitor C2. Although the antenna L1 is illustrated as a signal circuit device, it should be appreciated by one skilled in the art of to RF antenna design that the antenna L1 is physically a long distribution inductor (for example, with a length in a range of 1 cm to 30 cm) that transfers power to plasma in the plasma chamber 106 (see above, FIG. 1A). The method of power transfer can be through inductive coupling (e.g., with higher current) or capacitive coupling (e.g., with higher voltage). When operating in capacitive coupling mode the higher voltage section of the antenna L1 may create high electromagnetic field at the dielectric surface (e.g., of the dielectric plate 114) and enable plasma ignition at low pressure. The location of the high voltage fields can be controlled from one end to the other of the antenna L1 by, for example, adjusting the capacitors C1 and C2. When operating in an inductive coupling mode the peak current along the antenna L1 can be moved from end to end. This may also directly change the locating of the high plasma density region in the plasma chamber 106 to be near the capacitor C1, near the center of the antenna L1 or near the capacitor C2. When pulsing plasma and electronically controlling the antenna L1, the plasma density is controlled by region. The high density regions can shift locations within a pulse in a radial direction (such as from a region 322 to a region 312; see below, FIG. 2A) and in an azimuthal direction (such as between regions 312 at a same radial distance from the center point 330; see below, FIG. 2A). The plasma coupling method can change from capacitive to inductive coupling during a pulse in a few microseconds, or the plasma coupling can be balanced to maintain a combination of both coupling methods with one antenna plasma power transfer area. In some embodiments, different coupling methods operate in different physical regions (e.g., regions 312 and 322; see below, FIG. 2A) at the same time.

FIG. 1G illustrates a schematic for a floating LC circuit that may be driven inductively and used as a fundamental circuit for inductive tuning (see below, FIG. 4A). For example, the floating LC circuit of FIG. 1G may be duplicated a suitable number of times (e.g., eight times) and used near an LC antenna circuit in order to inductively tune the LC antenna circuit. In some embodiments, the inductor L1′ has an inductance in a range of 10 nH to 10,000 nH, such as 1650 nH, and the capacitor C4 has a capacitance in a range of 5 pF to 10,000 pF, such as 1800 pF.

FIG. 2A shows a multizone and multiregional areas of control, and 2B show a multizone axisymmetric resonating structure 300 having an outer zone 310 surrounding an inner zone 320, in accordance with some embodiments. The outer zone 310 and inner zone 320 may also be referred to as radial zones. FIG. 2A illustrates a top view of the multizone resonating structure 300. In some embodiments, the outer zone 310 and the inner zone 320 have cylindrical shapes centered on a center point 330. The outer zone 310 and the inner zone 320 are also referred to as resonating structures, radial zones, or cavities. Although FIG. 2A is shown with two radial zones, subdivided into regions having cylindrical shapes, it should be appreciated that the shape of the regions (here, cylindrical) is non-limiting and other shapes may be similarly considered. Plasma generation by, e.g., an axisymmetric antenna will produce a cylindrical or round plasma. “Axisymmetric” as used in this disclosure includes structures (e.g., the example resonating structure 350; see below, FIG. 2B) that remain unchanged under rotations by an angle equal to 360/n about the axis of symmetry (e.g., through the center point 330), where n is an integer greater than 1.

The outer zone 310 and the inner zone 320 may each include respective radiating structures 210, capacitors, and conductive offsets as illustrated above in FIG. 1B. For example, the outer zone 310 and the inner zone 320 may each have a respective radiating structure 210 on their respective bottom sides. However, any suitable internal structure may be used for the outer zone 310 and the inner zone 320.

The outer zone 310, the inner zone 320, or both are divided into a number of regions, defined by grouping segments, or antennas. In the illustrated example of FIG. 2A, the outer zone 310 is divided into seven regions 312, and the inner zone 320 is divided into six regions 322. The regions 312 and 322 may also be referred to as azimuthal regions. However, each of the outer zone 310 and the inner zone 320 may be divided into any suitable number of regions 312 and 322, respectively, such as two to twenty regions each. The number of regions is only an example for a given area, operating frequency, and amount of uniformity needing to be controlled. For example, a large plasma treatment system used in displays may have over one hundred antenna segments.

The regions may be directly selected and controlled with radio frequency (RF) pulse modulation (e.g., modulating duty cycle, frequency, or power), electronic impedance control, or a combination thereof. Tuning of the regions to achieve asymmetric plasma densities may be achieved by capacitive or inductive circuit coupling to the regions. This may be useful for enabling plasma ignition at low pressures and for compensating for non-uniform chamber effects or non-uniformities in wafers to be processed. Sensors (e.g., voltage or optical sensors) may be mounted on each region and even on each antenna segment for uniformity control of the regions. In other words, the sensors may be useful for maintaining specific amounts of azimuthal or radial uniformity by change in provided power between the regions during tuning and ignition, and then over a longer time during a processing step. Examples of optical sensors include discrete photodiodes and optical emission spectroscopy (OES) systems. These may be coupled by optical pipes or fibers to multiplexed optical measurement points, such as points above the plasma looking in from the top side of the plasma chamber 106 through the dielectric plate 114 or points around the edge of the dielectric plate 114 in order to look in through the side of the dielectric plate (see above, FIG. 1A). As an example, discrete photodiodes may be coupled by optical pipes or fibers to measure along antennas or around the plasma chamber 106 at multiple radiuses. Optical sensors may also be positioned by configurable regions, such as regions 312 of the outer zone 310 or regions 322 of the inner zone 320.

FIG. 2B illustrates a perspective view of an example resonating structure 350 having a radiating structure, also referred to as an antenna structure. In some embodiments, the radiating structure is a conductive, planar, closed ring structure with a plurality of antennas 362 (also referred to as spiral arms). The antennas 362 have n-fold symmetry about an axis which passes through the center point 330. In FIG. 2B, the number of antennas 362 is shown to be eight; however, the number of spiral arms 1208 is non-limiting and can be any number greater than one. The antennas 362 may form radiating structures 210 (see above, FIGS. 1B-1C) and are coupled to conductive plates 205 through conductive offsets 208. In some embodiments, one or more of the antennas 362 are electrically isolated from each other, such as by air gaps or dielectric material between the antennas 362 and the inner or outer rings of the radiating structure. Various examples of suitable radiating structures are described in U.S. patent application Ser. No. 17/649,823, which is incorporated herein by reference in its entirety.

In embodiments in which the antennas 362 are part of a unibody antenna (e.g., an axisymmetric unibody antenna), inductive circuits (see below, FIGS. 4A-4C) at the edges of the unibody antenna may couple with the magnetic field near the unibody antenna and thus change the current distribution in the antenna. In embodiments in which the antennas 362 are separated on at least one end, inductive circuits at the edges of the antennas 362 act locally on each antenna 362 and may provide more discrete control of current in each antenna 362. When antennas 362 are combined with a common capacitor (for example, a conductive plate 205 connecting to more than one radiative structure 210; see above, FIG. 1B), then the set of antennas 362 with a common capacitor form a region of control that may use only one tuning mechanism, which can be inductive or capacitive.

In some embodiments, the conductive plates 205 are segmented and/or electrically isolated from each other. In other embodiments, the conductive plates 205 are part of a continuous or unibody conductive plane that forms a part of a unibody capacitor. In embodiments having a unibody capacitor, capacitive circuits (see below, FIGS. 3A-3E) at the edges of the unibody capacitor may change the electric field distribution in the unibody capacitor. In embodiments having segmented conductive plates 205 forming segmented, separated capacitors, capacitive circuits may provide more discrete control of electric field and current distribution in each capacitor and coupled antenna (which may be segmented or part of a unibody antenna). Capacitive circuits can couple to each segmented capacitor to allow for larger segment resonance changes between segmented zones, even in embodiments with unibody antennas.

Capacitive coupling circuits or inductive coupling circuits can be used to tune the resonant frequencies or relative power outputs of antennas in radial and azimuthal zones, thereby achieving control of plasma densities in radial and azimuthal directions. FIGS. 3A-3E illustrate examples of capacitive coupling circuits, and FIGS. 4A-4C illustrate examples of inductive coupling circuits. The coupling circuits adjust relative distribution of power to the antennas while being outside the coupling of power from the power source (e.g., an RF source 102; see above, FIG. 1A) to the antennas. The coupling circuits may be reactive circuits or circuits with resistive elements (e.g., a low resistance metal that does not degrade with time). The choice of capacitive or inductive coupling for control of relative power to the various zones may be made based on the magnitude of desired control, the mechanical access to the various zones, and the magnetic coupling sensitivity over full power and frequency operating spaces. In some embodiments, a hybrid coupling including inductive coupling to one zone and capacitive coupling to another zone may be used. This may achieve isolated control of each zone with a least sensitive method, while taking into account mechanical design constraints that may limit access to each zone with inductive or capacitive circuits.

FIGS. 3A-3B illustrate multizone resonating structures 400 with capacitive circuit control of zones. Capacitive circuit control can be achieved by using electronic switching of a capacitor directly to ground as illustrated by FIG. 3A or by opening or closing capacitor segments coupled to an antenna as illustrated by FIG. 3B.

FIG. 3A illustrates a cross-sectional view of a multizone resonating structure 400 featuring an external capacitive circuit that is a detailed example of the multizone resonating structure 300 described above with respect to FIG. 2A. The example of FIG. 3A includes an outer zone (e.g., an outer zone 310; see above, FIG. 2A) containing an outer region (e.g., a region 312; see above, FIG. 2A). The outer zone surrounds an inner region (e.g., a region 322; see above, FIG. 2A) of an inner zone (e.g., a region 322 of an inner zone 320; see above, FIG. 2A) centered on an axis 410. The multizone resonating structure 400 is illustrated without including any power feeds or matching circuits. However, it should be appreciated that the multizone resonating structure 400 is a non-limiting example and embodiments may include any suitable combination of power feeds or matching circuits as described above or below. Additional examples of suitable multizone resonating structures are described in U.S. patent application Ser. No. 17/748,737, which is incorporated herein by reference in its entirety.

Capacitors 206A, 206B, 206C, and 206D are formed by the coupling of conductive plates 205 to the ground plane 202 across the insulating structure 204. Although the ground plane 202 is illustrated as grounded, the ground plane 202 may be floating or coupled to any suitable reference voltage. Each of capacitors 206A, 206B, 206C, and 206D may be either grounded, floating, or coupled to any suitable reference voltage. The conductive plates 205 may be parts of a unibody plate that form a larger unibody capacitor, or the conductive plates 205 may be separate segments of a larger conductive plate. In some embodiments where, e.g., one capacitor is grounded and another capacitor is floating, the ground plane 202 has a gap or dielectric structure electrically isolating the grounded capacitor from the floating capacitor. In the illustrated embodiment of FIG. 3A, a portion of the insulating structure 204 extends to a top surface of the ground plane 202 to provide an insulated electrical coupling between the capacitor 206A and a capacitor 402 used to tune the capacitive coupling of the outer zone segment (see below).

In the illustrated embodiment of FIG. 3A, the outer zone segment has an outer capacitor 206A and an inner capacitor 206B, and the inner zone segment has an outer capacitor 206C and an inner capacitor 206D. In other embodiments, the outer zone and inner zone may have different numbers or configurations of capacitors. For example, the outer zone and inner zone may have a shared capacitor and a shared conductive offset at their boundary.

In some embodiments, the respective radiating structures 210 include eight arms with Archimedean spiral shapes disposed between a respective inner ring and a respective outer ring (see above, FIG. 2B). Each arm of the respective radiating structures 210 may be coupled through the respective inner and outer rings to capacitors (e.g., capacitors 206A, 206B, 206C, and 206D). In other embodiments, the arms are electrically isolated from each other by slits or dielectric material.

The embodiment illustrated by FIG. 3A includes a mechanism for varying the resonant frequency of an outer zone segment including the floating capacitor 208A with an externally mounted capacitor 402 and a switch 406. The capacitor 402 and the switch 406 are on an opposite side of the insulating structure 204 from the radiating structure 210. The resonant frequency of the radiating structure 210 coupled to the capacitor 208A is tuned by opening and closing a switch 406 between ground and a capacitor 402 coupled to the conductive plate 205 of capacitor 208A. Coupling and decoupling the capacitor 402 with ground will change the capacitance by combining the capacitor 402 with the capacitor 206A or operating with the capacitor 206A alone and thus changing the impedance of the coupled radiating structure 210. This allows for the tuning or de-tuning of the resonance of the coupled radiating structure 210 without changing the resonance of other radiating structures 210, resulting in a non-uniform current distribution to the various radiating structures 210. Changing the capacitance of the coupled radiating structure 210 may shift the resonant frequency of the coupled radiating structure 210 up or down, which may increase or decrease the power coupled by the zone segment (e.g., the outer zone segment of FIG. 3A).

The switch 406 may be a semiconductor device such as a MOSFET (see below, FIGS. 3D-3E) or an SiC or GaN transistor controlled by a controller 404 (e.g., a processing unit such as a microprocessor with appropriate high voltage control isolation). The switching may include a RF sinusoidal switch or a rectified switch that has a diode in parallel, a diode in series, or a combination thereof. The switching voltages may be less than 5 kV, such as in a range of 1 kV to 2 kV, which is suitable for solid state switches (e.g., commercial high voltage semiconductor switching technology). These may be embedded on printed circuit board (PCB) structure that can be mounted on the ground plane 202. Power tuning for the radiating structure can be performed by pulsing the switch 406. The switch 406 may be pulsed and synchronized with pulsing of supplied power to drive current to a specific location during a pulsed plasma process, such as forcing the power to the center of the radiative structure 210 or to the edge of the radiative structure 210. In some embodiments, a variable capacitor may be used in place of or in addition to a switch 406 and a fixed capacitor 402.

The externally mounted capacitor 402 and switch may be implemented with discrete components, which is advantageous for easier service access. Although FIG. 3A illustrates the capacitor 402 as being coupled to the floating capacitor 208A of an outer zone segment, in other embodiments the capacitor 402 is coupled to a floating capacitor of an inner zone segment (e.g., capacitor 208C or 208D).

In various embodiments, two or more regions may each have their own respective capacitive circuits. Rotational plasma mixing can be performed by pulsing switches 406 coupled to each region in a rotational pattern. A control scheme may be implemented to smooth generated plasma density in real time using this rotational plasma mixing by pulsing the switches 406 in a rotational pattern.

FIG. 3B illustrates an embodiment similar to the embodiment of FIG. 3A but with a capacitive circuit including a capacitor 408 that may be co-planar with a floating capacitor 206A of an outer zone segment. The capacitor 408 is formed by the coupling of another conductive plate 205 to the ground plane 202 across the insulating structure 204. The conductive plate 205 of the capacitor 408 may be manufactured in a same process as the other conductive plates 205 of the outer and inner zones (e.g., capacitors 206A, 206B, 206C, and 206D) from a unibody or segmented plate. This may enable a cost effective process such as a printed circuit board manufacturing process to be used to form the capacitor 408. A controller 404 is coupled to a switch 406 (e.g., a semiconductor device or mechanical method) that couples the conductive plate 205 of the capacitor 408 with the conductive plate of the capacitor 206A. A same side of the insulating structure 204 faces the switch 406 and the radiating structure 210. Although FIG. 3B illustrates the capacitor 408 as being coupled to the floating capacitor 208A of an outer zone segment, in other embodiments the capacitor 408 is coupled to a floating capacitor of an inner zone segment (e.g., capacitor 208C or 208D).

FIGS. 3C-3E illustrate schematics of a capacitive circuit for controlling the resonating frequency of an antenna L2 (e.g., a radiative structure 210; see above, FIGS. 3A-3B) in various closed and open states. FIG. 3C shows a schematics of a capacitive CLC circuit in which the antenna L2 is coupled in a circuit with a first combined capacitor C5+C6 (e.g., a capacitor 208A and a capacitor 402, respectively) and a second combined capacitor C7+C8 (e.g., a capacitor 208B and another capacitor 402, respectively).

FIG. 3D shows a schematic of the capacitive circuit of FIG. 3C in a closed state with a first switch S1 set to closed by a controller 404 that couples the capacitor C5 to ground in parallel with the capacitor C6 and a second switch S2 set to closed by a controller 404 that couples the capacitor C8 to ground in parallel with the capacitor C7. The first switch S1 and second switch S2 are illustrated as block diagrams that may represent any suitable switching devices (e.g., semiconductor circuits or switches 406 such as MOSFETs). In some embodiments, the first switch S1 and the second switch S2 are switching devices that can be set to on, off, 50% on, or other partial or variable on/off states.

FIG. 3E shows a schematic of the capacitive circuit of FIG. 3C with the first switch S1 and the second switch S2 open so that capacitors C5 and C8 can be controlled by any method. By opening and closing the switches S1 and S2, the capacitance on each side of the antenna L2 may be changed. This shifts the resonant frequency of the antenna L2 up and down, allowing the resonating frequency of one zone segment to be tuned with respect to other zone segments. By tuning the resonating frequencies of zone segments with respect to each other, plasma ignition at low pressures may be achieved or plasma density uniformity during processing adjusted to account for non-uniform chamber effects or non-uniformities in wafers to be processed. In some embodiments, the switch S1 or the switch S2 is pulsed (in other words, opened and closed repeatedly) to change the resonant frequency of the antenna L2. In other embodiments, the switches S1 and S2 are alternately pulsed to shift the resonant frequency of the antenna L2, which may move power coupling from the antenna L2 to a plasma between opposite sides of the antenna L2.

FIG. 4A illustrate a multizone resonating structure 500 with inductive circuit control of outer regions. The multizone resonating structure 500 is similar to the multizone resonating structure 400 as described above. One or more mutual coupling coils 510 are located adjacent to a region or to a specific inductive segment (e.g., outer regions 312 or inner regions 322; see above, FIG. 2A) to change the resonant frequency of a region through mutual coupling of the magnetic fields from radiative structures 210 by inductive coupling 520 between the mutual coupling coils 510 and the radiative structures 210. In the illustrated embodiment of FIG. 4A, mutual coupling coils 510 are located adjacent to two outer regions. However, any suitable number of mutual coupling coils 510 may be used to couple with radiative structures 210 of any suitable number of outer regions or inner regions.

In some embodiments, the mutual coupling coils 510 are mounted on walls adjacent to the radiative structures 210, e.g. on conductive sidewalls 202A extending down from the ground plane 202. The mutual coupling coils 510 may be coupled to controllers 404, which may open and close switches (see below, FIGS. 4B-4C) to change the inductive coupling 520. The mutual coupling coils 510 may be used to separately tune the magnetic fields produced by the radiative structures 210 by changing magnetic fields around the radiative structures 210 or power drive circuits (not illustrated). It should be noted that the resonance with a mutual inductor can be implemented at any location that can couple to the RF magnetic fields in a local region. For example, in the schematics described below with respect to FIGS. 4B and 4C, any location physically close to the current path flowing between capacitors C6 and C7 through the antenna L2 will create a mutual coupling and shift the resonant frequency of the antenna L2. This circuit is also not restricted to one inductor, but may include additional RLC and semiconductor components with the intention of precise control of a selective region. This may enable fine tuning of generated plasma densities to compensate for non-uniform chamber effects or non-uniformities in wafers or to enable plasma ignition at low pressures.

FIGS. 4B-4C illustrate schematics of an inductive circuit for controlling the power output of an antenna L2 (e.g., a radiative structure 210) in various closed and open states. FIG. 4B shows a schematic of an inductive circuit in which an antenna L2 is coupled in a CLC circuit with a capacitor C6 (e.g., a capacitor 208A) and a capacitor C7 (e.g., a capacitor 208A and another capacitor 402, respectively). An inductive loop with an inductor M1′ (e.g., an mutual coupling coil 510) is adjacent to the CLC circuit. The inductor M1′ is mutually coupled with an inductor M1 between the antenna L2 and the capacitor C6. The inductive loop of FIG. 4B is in an open state with a third switch S3 (e.g., a switch 406 such as a MOSFET) set to open by a controller 404 so that the inductor M1′ is coupled to ground on only one side. Although the inductive loop is illustrated on the side of the capacitor C6, another inductive loop (not illustrated) may be present on the side of the capacitor C7.

The third switch S3 may be a transistor such as a MOSFET device (see above, FIGS. 3D-3E) embedded in or mounted on a wall of the structure (see above, FIG. 4A) to control the coupling of the inductor M1′ with ground. Mounting the inductive circuit and control on the wall of the structure can provide additional localization, which may increase circuit performance. The third switch S3 may be pulsed and synchronized with pulsing of supplied power to drive current to a specific location during a pulsed plasma process, such as forcing the power to the edge of the radiative structure 210 or to the center of the radiative structure 210. Magnetic flux induced voltages with the inductive loop in an open state may be low enough (e.g., less than 5 kV, such as in a range of 1 kV to 4 kV) to work with commercial high voltage switching technology.

FIG. 4C shows a schematic of the inductive circuit of FIG. 4B with the third switch S3 closed so that an inductor L3 is coupled to ground on two sides to form a grounded inductive loop. Although the inductor L3 replaces the inductor M1′ from FIG. 4B and no inductor M1 is illustrated in FIG. 4C, it should be understood that the inductor L3 may mutually couple with a portion of the circuit between the antenna L2 and the capacitor C6. By opening and closing the switch S3, the inductive coupling between the antenna L2 and the inductor L3 may be changed. This shifts the resonant frequency of the antenna L2 up or down, allowing the power output of one region to be tuned with respect to other regions and zones. By tuning the power output of regions with respect to each other, plasma ignition at low pressures may be achieved or plasma density uniformity during processing may be adjusted to account for non-uniform chamber effects or non-uniformities in wafers to be processed.

FIG. 4D illustrates frequency shifts with mutual inductive coils adjacent to two regions. The mutual inductive loops are enabled by forming a closed loop operating in a grounded and open states. Trace 550 shows frequency distributions from two regions, such as a first region and a second region, operating as one system(e.g., all antennas 362 operating as one system; see above, FIG. 2B) when inductive loops adjacent to both the first region and the second region are open so that no mutual coupling is present. Traces 560 and 570 show frequency distributions when the antennas 362 are configured the antennas into a first region and a second region. Trace 560 shows a frequency distribution from when the second region is enabled and the inductive loop adjacent to it is a grounded inductive loop. Trace 570 shows a frequency distribution from when the first region is enabled and the inductive loop adjacent to it is a grounded inductive loop.

FIGS. 5A-5B illustrate control schemes for plasma processing systems, in accordance with some embodiments. FIG. 5A is a flow chart of a control scheme for a first region and a second region (e.g., a region 312 and a region 322, or a group of regions in the outer zone 310 radial set). First region settings 630 are input into a first region controller 602 and first region uniformity settings 632 are input into a first region uniformity controller 604. The first region controller 602 and the first region uniformity controller 604 may be processing units such as microprocessors. In some embodiments, the first region uniformity controller 604 is implemented as an additional control loop in the first region controller 602 to manage uniformity adjustment using sensors 620 for feedback.

The first region settings 630 may include parameters for plasma generation such as power, frequency, and modulation. The first region uniformity settings 632 may include parameters for adjusting the resonant frequency and/or power of the first region relative to other regions (e.g., the second region). Sensors 620 such as voltage-current (V-I) or optical sensors provide real time feedback to the first region controller 602 and the first region uniformity controller 604 on the density and energy in the plasma chamber and on power supplied to the first zone.

The first region controller 602 and the first region uniformity controller 604 exchange data in real time to achieve desired power and tuning of the first region so that plasma density shifts are predictable. For example, if the first region controller 602 increases power to the first region, the first region uniformity controller 604 may use the increase in power to adjust the uniformity using frequency, power or modulation tuning so that a consistent percent shift is maintained over the power increase.

The first region controller 602 produces output 640, which may include parameters such as power, frequency, and modulation, to control a power source (e.g., an RF source 102; see above, FIG. 1A) for the first region. In some embodiments, the power source includes a power amplifier that receives instructions from the output 640. The first region uniformity controller 604 produces uniformity output 642 to control switches in capacitive or inductive circuits to define first region.

The second region may have a similar control scheme as the first region, with a second region controller 612 similar to the first region controller 602 and a second region uniformity controller 614 similar to the first region uniformity controller 604. The second region controller 612 receives second region settings 650 and the second region uniformity controller 614 receives second region uniformity settings 652 similar to the first region settings 630 and first region uniformity settings 632, respectively. Sensors 620 provide feedback to the second region controller 612 and the second region uniformity controller 614, which exchange data in real time with each other. The second region controller 612 produces output 660 and the second region uniformity controller 614 produces region output 662 to control a power source for the second region and to control switches in capacitive or inductive circuits for defining the second region, respectively. The first region settings 630, the first region uniformity settings 632, the second region settings 650, and the second region uniformity settings 652 may be supplied by a controller for the entire multizone system, e.g. a controller 702 (see below, FIG. 5B).

FIG. 5B is a control chart for a control scheme 700 of a multizone resonating structure, in accordance with some embodiments. A controller 702 provides settings in real time to a module controller 718 for each region. The module controller 718 then applies the settings to a power source 720, which supplies power to each region and may pulse switches of capacitive circuits or inductive circuits to achieve desired plasma densities. The power source 720 may be an inductively coupled plasma (ICP) source or a capacitively coupled plasma (CCP) source. In some embodiments, the CCP source is divided up into segments and the resonant control of each CCP source segment is excited by mutual coupling coils like the ICP antennas described above with respect to FIGS. 4A-C.

In some embodiments, the controller 702 is a machine learning (ML) based controller, such as a microprocessor configured to run a live machine learning mode. The controller 702 includes a regional pulse controller 704 and a regional electronic switching controller 706. The regional pulse controller 704 and the regional electronic switching controller 706 may be similar to the first regional controller 602 and the first regional uniformity controller 604, respectively, described above with respect to FIG. 5A. The regional pulse controller 704 and the regional electronic switching controller 706 may exchange regional settings in real time to control plasma density shifts.

The regional pulse controller 702 receives input from region sensors, which may include one or more zone V-I sensor(s) 708, RF V-I sensor(s) 710, optical sensor(s) 712, and RF power sensor(s) 714. Optical measurements from the optical sensor(s) 712 can be used for plasma density feedback control. The region V-I sensor(s) 708 can provide a strong tuning feedback control signal. This can be combined with forward and reflected power from RF V-I sensor(s) 710 for a robust set of multiple inputs for feedback control. The controller 702, configured to run a live machine learning model, can use feedback from the sensors to map to chamber condition changes per process step (such as changes in power, pressure and, chemistry). This can maintain uniformity over process step, wafer to wafer, and chamber clean life cycles.

FIG. 6 is a graph showing plasma ignition at a low pressure by focusing power with a single region (e.g., a one or more combined regions 312 or 322; see above, FIG. 3A). Focusing power with a single region may enable plasma ignition at extremely low pressures, and the location of the ignition may be managed predictably and repeatedly. As power is applied disproportionately to resonant region(s), voltage on the antenna(s) of the region increases until electric field at a dielectric top (e.g., dielectric plate 114; see above, FIG. 1A) triggers a plasma discharge to ignite the plasma. After plasma ignition, power may be regulated among the regions to achieve a desired plasma density, such as a uniform plasma density.

In FIG. 6, trace 752 is voltage on the antenna of the region, trace 754 is reflected power measured at the power source, trace 756 is output of a photodiode sensor, and dashed line 758 is the time at which ignition occurs. At zero time, the voltage on the antenna is ramped up and reflected power increases with the voltage until the reflected power has an inflection resonance and sharply declines. Voltage peaks at the time of ignition and can then be decreased to maintain the plasma. The photodiode signal increases from 0 at the time of ignition as it begins measuring light from the ignited plasma. In some embodiments, ignition occurs at a time after the start of ramping up the voltage in a range of 2 us to 100 μs, such as 6.3 μs. In some embodiments, peak voltage at ignition is in a range of 50 V to 4000 V, such as 556 V.

In the illustrated example of FIG. 6, argon gas is ignited to plasma at a pressure of 0.267 mT. However, any suitable gas may be used for the plasma, such as oxygen (O₂), nitrogen (N₂), hydrogen (H₂), neon, krypton, C₄F₈, HBr, Cl, SF₆, the like, or a combination thereof. The plasma can be ignited at an extremely low pressure, such as a pressure in a range of 0.2 mT to 1000 mT.

FIGS. 7A-7C illustrate plasma power pulse recipe with three phases (i.e., power levels) for plasma processing, in accordance with some embodiments. FIG. 7A illustrates the average applied power per phase graphed versus time.

FIG. 7B shows an example for RF pulsing by region of a multizone resonating structure, in which power from the pulse recipe of FIG. 7A is distributed between two regions to produce a three-phase pulse pattern with a 2180 microsecond (μs) period. The three-phase pulse pattern has a first phase of 860 us at high power, a second phase of 680 us at medium power, and a third phase of 620 us with power off. FIG. 7B shows an example with a sub-pulse control methodology for plasma processing with a two-step square wave graphed as applied power over time as in FIG. 7A. It should be appreciated that the waveform of FIG. 7B is a non-limiting example, and any suitable waveform may be used for pulsed plasma processing. As an example, in a multizone resonating structure with eight zone segments, region 1 includes seven antenna segments and region 2 includes the remaining antenna segment. As shown in FIG. 7B, the delivered pulsed power of the recipe is alternated between region 1 and region 2 during each sub-pulse of the three-phase pulse pattern. In the example of FIG. 7B, the power supplied to region 2 is less than the power supplied to region 1. However, any suitably distribution of power between regions 1 and 2 may be used, such as multi-tone power in which more than one frequency and amplitude are combined.

FIG. 7C shows an example recipe for RF pulsing by region similar to the recipe of FIG. 7B but including a plasma ignition step. The applied power per region is graphed versus time. The plasma density versus time is also illustrated. As shown in FIG. 7C, each pulse begins with a much higher distribution of power to region 2 in order to ignite the plasma. After plasma ignition, the recipe reverts to the alternating pattern of FIG. 7B in which region 1 receives a significantly larger amount of power than region 2. As an example, during ignition region 2 receives a first amount of power and region 1 receives a second amount of power that is less than the first amount of power, while after ignition region 2 receives a third amount of power and region 1 receives a fourth amount of power that is greater than the third amount of power. As another example, during ignition region 2 receives power with a greater area density (in other words, with a higher electrical or inductive power delivered to a smaller area) than the area density of power supplied to region 1 during ignition, while after ignition region 2 receives power with a same or lesser area density than power supplied to region 1. The area density of power supplied to region 2 during ignition may be greater than the area density of power supplied to region 1 during ignition, even if the total amount of power supplied to region 1 is greater than the total amount of power supplied to region 2 during ignition.

In some embodiments, Power is supplied to region 1 and region 2 by pulsing power discretely between a first frequency and a second frequency. The first frequency is closer to the resonant frequency of the first region and the second frequency is closer to the resonant frequency of the second region, so that power supplied at the first frequency couples to the first region and power supplied at the second frequency couples to the second region.

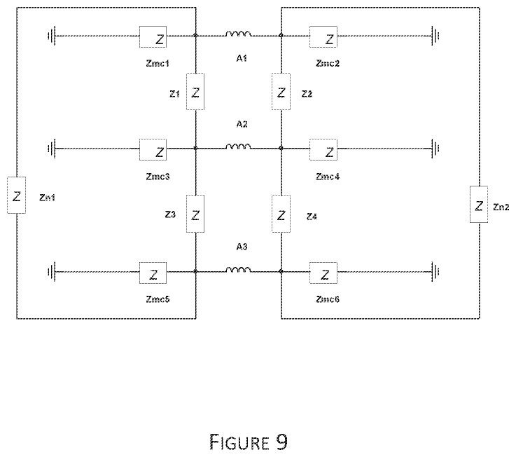

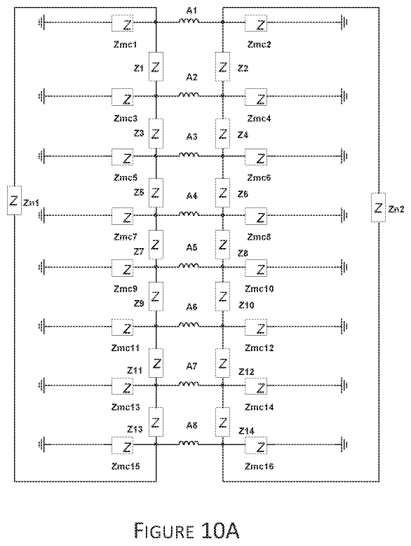

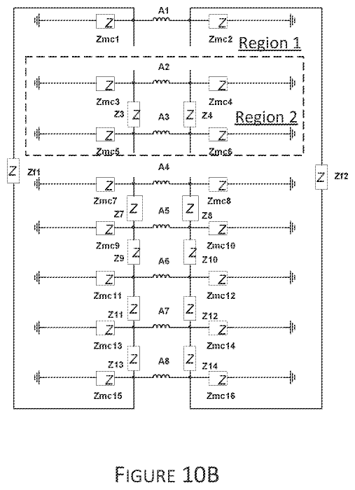

FIGS. 8A-10B are schematics of example circuits for multi-region inductively coupled plasma (ICP) systems with various numbers of regions. FIGS. 8A-8B illustrate example circuits for an ICP system configurable for two regions, FIG. 9 illustrates an example circuit for an ICP system configurable for three regions, and FIGS. 10A-10B illustrate an example circuit for an ICP system configurable for eight regions. The regions can be configured to work together as a single region or as multiple regions, each region including one or more antenna circuit. Each region may be power balanced with a preference for peak power delivery during ignition and average power preference set to one end of the antenna(s) of the region. The antennas being arranged in a radial pattern such as an Archimedean spiral (see above, FIG. 2B) can control balance and enable radial power distribution (also referred to as radial control).

FIG. 8A is a schematic of an example circuit for a two antenna ICP system that can be configured to act as one or two regions. The example circuit includes an antenna A1 for a first region and an antenna A2 for a second region. The antenna A1 is coupled to ground across Zmc circuits Zmc1 and Zmc2, and the antenna A2 is coupled to ground across Zmc circuits Zmc3 and Zmc4.

The circuit further includes impedance control circuits, also referred to as Z circuits, between antenna segments on each end, and Zmc circuits. The Zmc circuits Zmc1 to Zmc4 can interact by mutual inductance, varying capacitance, or by directly changing the impedance (in other words, increasing or decreasing capacitance) to shift the resonance of one end of the antennas A1 and A2. The Zmc circuits can be short or open circuits. By changing the values (e.g., the capacitances or inductances) of the respective Zmc circuits, power will couple to the antennas by controlling the frequency of the antennas (e.g., the antennas A1 or A2). This may enable changing the balance of power distributed among regions after a first ignition pulse (e.g., changing the power balance in a pulse between regions 1 and 2 after ignition; see above, FIG. 7C). Changing the values of the Zmc circuits may be performed electronically (e.g., with voltage tuned capacitance of a varactor) or mechanically (e.g., by adjusting distances between parallel plates of capacitors).

The nodes between the antennas A1 and A2 and the Zmc circuits are coupled through Z circuits Z1 and Z2. The Z circuits represent inductive or capacitive circuits that may be arranged as parallel or series LRC circuits. These circuit elements control power balance and current balance between regions and influence the resonant frequency of the regions. The LRC circuits may be open or short. The values of the Z circuits (e.g., the capacitances or inductances) may be electronically adjustable or mechanically adjustable. The Z circuits may include diodes and controllable semiconductor devices. The circuits Z1 and Z2 may be set to closed in order to operate the two antennas as one region, or the circuits Z1 and Z2 may be set to open in order to operate the two antennas as two independent regions.

FIG. 8B is a schematic of the circuit of FIG. 8A showing internal components of the Zmc circuits, in accordance with an embodiment. The Zmc1 circuit has a capacitor C1 and a Zc1 circuit coupled in parallel between ground and the node between the antenna A1 and the Z1 circuit. A loop with a Zm1 circuit and inductor M1 is coupled to an inductor M1′ (such as a supporting metal conductor) between the capacitor C1 and the antenna A1. The Ze1 circuit can be used to adjust capacitance through a parallel capacitance with the capacitor C1, and the Zm1 circuit can be used to adjust inductance through mutual inductance with the inductor M1. Likewise, the other Zmcx circuits contain respective capacitors Cx, Zcx circuits, Zmx circuits, and inductors Mx and Mx′ with similar arrangements, where x is a number from 2 to 4.

FIG. 9 is a schematic of an example circuit for a three antenna ICP system that can be configured to act as one, two, or three regions by opening or closing appropriate Z circuits. The circuit of FIG. 9 is similar to the circuit of FIG. 8A with the addition of a third antenna A3 that is coupled to ground at its ends by Zmc circuits Zmc5 and Zmc6. Z circuits Z3 and Z4 couple the antenna A3 to the antenna A2, and Z circuits Zn1 and Zn2 couple the antenna A3 to the antenna A1. The antenna A3 (or an antenna A8 or any other final antenna; see below, FIGS. 10A-10B) may be physically adjacent to the antenna A1, such as when the antennas A1-A3 are spiral arms of an antenna structure with n-fold symmetry (see above, FIG. 2B).

FIG. 10A is a schematic of an example circuit for an eight zone ICP system that is configured to act as one region with all Z circuits being closed. The circuit of FIG. 10A is similar to the circuits of FIG. 9 with the addition of antennas A3 to A8, Zmc circuits Zmc7 to Zmc16, and Z circuits Z5 to Z14. The Z circuits Zn1 and Zn2 couple the antenna A8 to the antenna A1. Although the circuit of FIG. 10A is illustrated as being configured to act as one region, it may be configured to act as any of two to eight regions by opening or closing appropriate Z circuits.

FIG. 10B is a schematic of the example circuit of FIG. 10A for an eight zone ICP system that is configured to act as two regions with circuits Z1 to Z4 (see above, FIG. 10A) being open. Region 1 includes: antennas A1 and A4-A8; Z circuits Z7-Z14, Zf2, and Zf2; and Zmc circuits Zmc1, Zmc2, and Zmc7-Zmc16. Region 2 includes: antennas A2 and A3, Z circuits Z3 and Z4, and Zmc circuits Zmc3-Zmc6. In some embodiments, power is focused into Region 2 at the start of a pulse to achieve plasma ignition, and power is then subsequently alternated between Regions 1 and 2 (see above, FIG. 7C).

FIG. 11 is a process flow chart diagram of a method 800 for plasma processing, in accordance with some embodiments. Step 802 is the start of a process recipe for a wafer (e.g., a substrate 110), which is placed into a plasma chamber 106 as described above with respect to FIG. 1A. In step 804, a check is made (e.g., by a controller 702; see above, FIG. 5B) if low pressure plasma ignition is desired, such as by checking a user-set parameter for low pressure plasma ignition. If low pressure plasma ignition is desired, the method proceeds to step 806; if low pressure plasma ignition is not desired, the method proceeds to step 808.

In step 806, the controller 702 configures recipe regions (e.g., Regions 1 and 2; see above, FIG. 10B) with an ignition pulse pattern, as described above with respect to FIGS. 6 and 7C. In step 808, the controller 702 configures the recipe regions for uniformity control over the regions (e.g., with a balanced power distribution over the regions such as with rotational plasma mixing), as described above with respect to FIG. 3A.

In step 810, the controller 702 executes the recipe which may include low pressure ignition followed by plasma uniformity, as described above with respect to FIGS. 5A-5B. In step 812, the controller 702 executes real-time uniformity control using real time plasma uniformity measurements, as described above with respect to FIGS. 5A-5B. Finally, in step 814, the wafer recipe is complete, and the wafer (e.g., the substrate 110) may be removed from the plasma chamber 106 or may be further processed in situ with additional recipes.

FIG. 12 is a process flow chart diagram of a method 900 for plasma processing, in accordance with some embodiments. In step 902, a substrate 110 is loaded into a plasma processing system 100, as described above with respect to FIG. 1A. The plasma processing system comprises a multizone resonating structure 300 (see above, FIG. 2A) that comprises a first region (e.g., region 2; see above, FIG. 7C) and a second region (e.g., region 1; see above, FIG. 7C) adjacent to the first region.

In step 904, plasma is ignited by providing a first amount of power to the first region and a second amount of power to the second region where the first amount is greater than the second amount, as described above with respect to FIG. 7C. In step 906, a plasma process is performed on the substrate 110, as described above with respect to FIG. 7C. The plasma process comprises producing a plasma with a uniform density by providing a third amount of power to the first region and a fourth amount of power to the second region, where the third amount of power is less than the fourth amount of power.

Adjusting power supplied to a plasma by zone (e.g., by azimuthal and/or radial zone segments) may compensate for chamber uniformity due to gas flow, non-uniformity of the antenna, or changes in power returning through the chamber walls or through RF paths that may change after a disassembly and assembly of the plasma processing apparatus. For example, adjusting the uniformity of the supplied plasma power can compensate for chamber changes occurring between wet clean processes. Adjusting the uniformity of the supplied plasma power may also allow for chamber to chamber matching in order to achieve a same plasma uniformity between process chambers with different non-uniformities.

In embodiments with segmented antennas, antennas in different radial zones may be raised and lowered to vary coupling areas by changing radial diameters and intensity. Vertical adjustments may reduce undesired partial sputtering from dielectric areas of top plates. A larger gap enabled by vertically adjusting the antenna's position reduces capacitive coupling between the antenna and generated plasma.

In some embodiments, the antenna is radially rotated to rotate the generated plasma. Resonant hot spots may occur due to paths of constant impedance for power flow in the process chamber. Rotating the antenna may reduce undesired partial sputtering from dielectric areas of top plates by preventing or reducing plasma from being drawn to the resonant hot spots.

In some embodiments, controlling plasma uniformity can achieve plasma ignition at lower pressures by enabling more power to be provided in a smaller area through, for example, switching on one azimuthal zone. Achieving ignition through high capacitive coupling is possible if the antenna is close to a dielectric structure (e.g., the dielectric plate 114; see above, FIG. 1A) between the antenna and the process chamber. Additionally, activating one zone segment may allow a greater amount of power to be focused in one spot to achieve ignition. After plasma ignition, the remaining zones may be switched on to achieve a more uniform density of plasma, if desired.

Real time control can balance power distribution with active measurement of plasma density by zone segment through optical or electric current or field measurements. The real time balancing of power distribution can control plasma impedances to produce desired shifts in plasma density. Radial and azimuthal control can be achieved by shifting power coupling locations underneath the inductively coupled plasma (ICP) antennas.

Measurements of plasma uniformity can be implemented for capacitive circuit control by measuring the current at a capacitor of a region using the relationship of current to capacitance and voltage:

$$I = C \frac{d V}{dt} .$$

Measurements of plasma uniformity can be implemented for inductive circuit control by using an inductive pickup with each antenna segment or group of antenna segments.

Optical measurement of the plasma density in the radial and azimuthal directions can be implemented by optical sensors located at the top surface of the dielectric structure (e.g., the dielectric plate 114; see above, FIG. 1A) near the primary power coupling areas for the antennas. The optical sensors can include photodiodes, charged-coupled device (CCD) cameras, the like, or a combination thereof. The optical sensors may be positioned at remote locations in order to be outside of the RF field. Optical transmission to the optical sensors can be achieved by using fiber optic bundles, light pipes, or optical tubes between the optical sensors and the apparatus to reduce photoemission loss. Optical camera images with wide angle pickups can be implemented through using multiple optical cameras with overlapping images and combining the images (for example, by using intensity and/or color matching) while subtracting the antenna structure from the combined image.

Optical sensors can be combined with pulse control to enable density measurements of radial or azimuthal regions and calculate the power balance delivered by sensing the pulse wave shape including ignition time delay, ramp time, pulse peaks and valleys, and total pulse area. One or more optical sensors may be used to sense the pulse wave shapes. Pulse optical response may be measured between radial regions and between azimuthal regions. For example, optical sensors can measure pulse shapes at a number of locations (e.g., 1 to 100 locations) to enable control of plasma uniformity by controlling and tuning radial power by region. An example of an optical sensor being at a single location is a CCD camera with a pickup larger than one region that may measure, e.g., a gradient of average or peak intensity across an area. An example of optical sensors being at 100 locations is an array of fiber optic sensors that may be combined across a CCD array or a photodiode array. Optical sensors may measure pulse shape data such as pulses with steady state intensity or the shapes of pulse ignition delays.

In some embodiments, a multizone resonating structure (also referred to as a resonant antenna system) has more than one region of control. The multizone resonating structure may have any suitable configuration of radial and/or azimuthal zones. The multizone resonating structure may have a rectangular source or bias or a focus ring plasma source. In some embodiments, antennas of the multizone resonating structure are segmented into groups, which may include regions of adjacent antennas or separate antennas. Power balance across regions of the multizone resonating structure may be achieved by control of the resonant frequency between each region. The frequency spectrum of provided power may include single or multiple sine waves (also referred to as “tones”) or may have a mix of broadband RF (also referred to as multi-frequency RF). Power balance delivery to each region may be controlled by applying power at one or more than one frequency to select the region, as the regions may be set to different resonating frequencies. This control over the amount of power distributed to resonant regions (by matching with the resonating frequencies of the regions) allows for the adjustment of plasma uniformity. Regional plasma density can be adjusted by applying power control per unit time delivered by frequency, amplitude, and pulse duration. Power absorbed by each region is controlled by impedance control (e.g., by Z and Zmc circuits) of each region that sets the frequency and bandwidth of absorbed power for each region. Z circuits are coupled between antennas and Zmc circuits are coupled at the ends of the antennas. Power may be applied to specific regions using pulse modulation with pulse steps. One or more optical intensity measurements of the plasma may be used for one or more regions for feedback control. One or more RF measurements (e.g., voltage or current measurements) can be used by region for feedback control to achieve power balance between regions. In some embodiments, feedback control combines optical intensity and RF measurements.

Region segmentation control can be achieved by configuring the impedance control of one or more antennas. In some embodiments, regional segmentation control is achieved by controlling Z circuits, Zmc, or both Z and Zmc circuits between antennas. In some embodiments, power balance along the antennas (e.g., power balance between antenna centers and edges is achieved by controlling Zmc circuits, Z circuits, or both Zmc and Z circuits coupled to the ends of each antennas.

A specific region for plasma ignition (e.g., an area or specific location in the plasma chamber where the plasma first ignites) may be determined by configuring impedance control elements (e.g., the Z and Zmc circuits) in order for a desired antenna to absorb power. The location of the plasma ignition may be controlled by controlling the frequency of the supplied power and the resonant frequency of the antenna.

Example embodiments of the disclosure are summarized here. Other embodiments can also be understood from the entirety of the specification as well as the claims filed herein.

Example 1. An apparatus for plasma processing, the apparatus including: an RF power source; and a set of resonating structures coupled to the RF power source, the resonating structures including: a first region including: a first antenna; and a first coupling circuit, the first coupling circuit being outside a coupling of the RF power source to the first region, where the first coupling circuit is configured to adjust a power distribution of the first region; and a second region adjacent to the first region, the second region including: a second antenna.

Example 2. The apparatus of example 1, where the first coupling circuit is a capacitive coupling circuit, the capacitive coupling circuit including a capacitor coupled to ground across a switch.

Example 3. The apparatus of example 2, where the switch is a semiconductor device.

Example 4. The apparatus of one of examples 2 or 3, where a resonating structure of the set of resonating structures further includes an insulating structure, a first side of the insulating structure facing the first antenna.

Example 5. The apparatus of example 4, where the first side of the insulating structure faces the switch.

Example 6. The apparatus of example 4, where the switch is on a second side of the insulating structure, the second side being opposite the first side.

Example 7. The apparatus of example 1, where the first coupling circuit is an inductive coupling circuit, the inductive coupling circuit including an mutual coupling coil.

Example 8. The apparatus of one of examples 1 to 7, further including: a controller, where the controller is coupled to the first coupling circuit, the controller being configured to control the first coupling circuit; and a sensor, the sensor being coupled to the controller, where the sensor provides real time feedback to the controller.

Example 9. The apparatus of example 8, where the sensor is a voltage sensor.

Example 10. The apparatus of example 8, where the sensor is an optical sensor.

Example 11. An apparatus for plasma processing, the apparatus comprising: a resonating structure, the resonating structure having a cylindrical or axisymmetric shape, the resonating structure comprising: a plurality of azimuthal regions, wherein a first azimuthal region of the plurality of azimuthal regions comprises a first antenna and a first impedance control circuit coupled to the first antenna, the first impedance control circuit configured to shift the resonance of one end of the first antenna, and wherein a second azimuthal region of the plurality of azimuthal regions comprises a second antenna and a second impedance control circuit coupled to the second antenna.

Example 12. The apparatus of example 11, where the first impedance control circuit is electronically or mechanically adjustable.

Example 13. The apparatus of one of examples 11 or 12, where the first antenna and the second antenna are electrically coupled to each other through a third impedance control circuit.

Example 14. The apparatus of example 13, where the coupling of the first antenna and the second antenna is electrically or mechanically controllable.

Example 15. The apparatus of one of examples 11 or 12, where the first antenna and the second antenna are part of a unibody antenna.

Example 16. The apparatus of one of examples 11 or 12, where the first antenna and the second antenna are electrically isolated from each other.

Example 17. A method for plasma processing, the method including: loading a substrate into a plasma processing system, where the plasma processing system includes a multiregional resonating structure, the multiregional resonating structure including a first region and a second region adjacent to the first region; igniting plasma by providing a first amount of power to the first region and a second amount of power to the second region, the first amount having a greater area density than the second amount; and performing a plasma process on the substrate, the plasma process including producing a plasma with a uniform density.

Example 18. The method of example 17, where performing the plasma process further includes supplying power to the first region at a first frequency while changing a resonant frequency of an antenna of the first region by pulsing a first switch coupled to a first side of the antenna.

Example 19. The method of example 17, where performing the plasma process further includes pulsing power discretely between a first frequency and a second frequency, where the first frequency is closer to the resonant frequency of the first region and the second frequency is closer to the resonant frequency of the second region.

Example 20. The method of one of examples 17 to 19, where producing the plasma with a uniform density includes rotational plasma mixing.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. An apparatus for plasma processing, the apparatus comprising:
an RF power source; and
a set of resonating structures coupled to the RF power source, the resonating structures comprising:
a first region comprising:
a first antenna; and
a first coupling circuit, the first coupling circuit being outside a coupling of the RF power source to the first region, wherein the first coupling circuit is configured to adjust a power distribution of the first region; and
a second region adjacent to the first region, the second region comprising:
a second antenna.

2. The apparatus of claim 1, wherein the first coupling circuit is a capacitive coupling circuit, the capacitive coupling circuit comprising a capacitor coupled to ground across a switch.

3. The apparatus of claim 2, wherein the switch is a semiconductor device.

4. The apparatus of claim 2, wherein a resonating structure of the set of resonating structures further comprises an insulating structure, a first side of the insulating structure facing the first antenna.

5. The apparatus of claim 4, wherein the first side of the insulating structure faces the switch.

6. The apparatus of claim 4, wherein the switch is on a second side of the insulating structure, the second side being opposite the first side.

7. The apparatus of claim 1, wherein the first coupling circuit is an inductive coupling circuit, the inductive coupling circuit comprising an mutual coupling coil.

8. The apparatus of claim 1, further comprising:
a controller, wherein the controller is coupled to the first coupling circuit, the controller being configured to control the first coupling circuit; and
a sensor, the sensor being coupled to the controller, wherein the sensor provides real time feedback to the controller.

9. The apparatus of claim 8, wherein the sensor is a voltage sensor.

10. The apparatus of claim 8, wherein the sensor is an optical sensor.

11. An apparatus for plasma processing, the apparatus comprising:
a resonating structure, the resonating structure having a cylindrical or axisymmetric shape, the resonating structure comprising:
a plurality of azimuthal regions, wherein a first azimuthal region of the plurality of azimuthal regions comprises a first antenna and a first impedance control circuit coupled to the first antenna, the first impedance control circuit configured to shift the resonance of one end of the first antenna, and wherein a second azimuthal region of the plurality of azimuthal regions comprises a second antenna and a second impedance control circuit coupled to the second antenna.

12. The apparatus of claim 11, wherein the first impedance control circuit is electronically or mechanically adjustable.

13. The apparatus of claim 11, wherein the first antenna and the second antenna are electrically coupled to each other through a third impedance control circuit.

14. The apparatus of claim 13, wherein the coupling of the first antenna and the second antenna is electrically or mechanically controllable.

15. The apparatus of claim 11, wherein the first antenna and the second antenna are part of a unibody antenna.

16. The apparatus of claim 11, wherein the first antenna and the second antenna are electrically isolated from each other.

17. A method for plasma processing, the method comprising:
loading a substrate into a plasma processing system, wherein the plasma processing system comprises a multiregional resonating structure, the multiregional resonating structure comprising a first region and a second region adjacent to the first region;
igniting plasma by providing a first amount of power to the first region and a second amount of power to the second region, the first amount having a greater area density than the second amount; and
performing a plasma process on the substrate, the plasma process comprising producing a plasma with a uniform density.

18. The method of claim 17, wherein performing the plasma process further comprises supplying power to the first region at a first frequency while changing a resonant frequency of an antenna of the first region by pulsing a first switch coupled to a first side of the antenna.

19. The method of claim 17, wherein performing the plasma process further comprises pulsing power discretely between a first frequency and a second frequency, wherein the first frequency is closer to the resonant frequency of the first region and the second frequency is closer to the resonant frequency of the second region.

20. The method of claim 17, wherein producing the plasma with a uniform density comprises rotational plasma mixing.
